(19) United States
(12) Patent Application Publication
(10) Pub. No.: US 2004/0233646 A1
(43) Pub. Date: Nov. 25, 2004

(54) Shell device with circuit unit

(76) Inventor: Chi-Yu Yen, Taipei City (TW)

Correspondence Address: BIRCH STEWART KOLASCH & BIRCH, PO BOX 747, FALLS CHURCH, VA, 22040-0747, US

(21) Appl. No.: 10/673,397

(22) Filed: Sep. 30, 2003

(30) Foreign Application Priority Data
May 23, 2003 (TW) 92209580

(51) Int. Cl. H05K 5/00; H05K 5/04; H05K 5/06

(52) U.S. Cl. 361/752

(57) ABSTRACT

A shell structure with a circuit unit is proposed. The shell has an inner surface on which the circuit unit is arranged for providing a modular structure and accomplishing easy design and manufacturing, thereby reducing the numbers of electronic components and the assembly process steps and saving the manufacturing cost and material.

### BACKGROUND OF THE INVENTION

1. Field of Invention

The present invention relates to a shell device with a circuit unit and, more particularly, to a device having a circuit unit installed in a shell thereof.

2. Description of Related Art

As shown in FIG. 1, in a conventional electronic product, electronic components 20a are arranged on a printed circuit board 10a, and upper and lower shells 30a conforming to the printed circuit board 10a are designed. It is also necessary to provide fixing components 40a (e.g., projective poles or fastening structures) on the shells 30a for firmly connecting the printed circuit board 10a, or the printed circuit board 10a is locked on projective poles. The printed circuit board 10a can thus be firmly connected in the shells 30a for circuit control of the electronic product.

However, because the printed circuit board is assembled on the fixing components of the shells, the processing procedure and the assembly time increase. Moreover, it is necessary to design fixing components on the shells, and the design cost, mold cost and material cost increase accordingly, hence increasing the product cost and thus lowering the competitive capability of the electronic product.

### SUMMARY OF THE INVENTION

One object of the present invention is to provide a shell device with a circuit unit, which can reduce the number of components to reduce the cost thereof.

Another object of the present invention is to provide a shell device with a circuit unit to reduce the processing procedure and time thereof.

Yet another object of the present invention is to provide a shell device with a circuit unit to reduce the design cost and mold cost thereof.

Still yet another object of the present invention is to provide a shell device with a circuit unit, wherein the circuit unit is arranged on an inner surface of the shell of any shape in a modular way.

To achieve the above objects, the present invention provides a shell device with a circuit unit. The shell device comprises a shell and a circuit unit. The shell has an inner surface. The circuit unit is arranged on the inner surface of the shell.

The present invention also provides another shell device with a circuit unit. The shell device comprises a shell, a circuit unit and an electric connection component. The shell includes an upper shell and a lower shell having inner surfaces. The circuit unit includes an upper circuit unit and a lower circuit unit, which are arranged on the inner surfaces of the upper shell and the lower shell, respectively. The electric connection component is electrically connected with the upper circuit unit and the lower circuit unit.

The various objects and advantages of the present invention will be more readily understood from the following detailed description when read in conjunction with the appended drawing, in which:

### BRIED DESCRIPTION OF THE DRAWINGS

The various objects and advantages of the present invention will be more readily understood from the following detailed description when read in conjunction with the appended drawing, in which:

FIG. 1 is an exploded perspective view of a conventional flash drive;

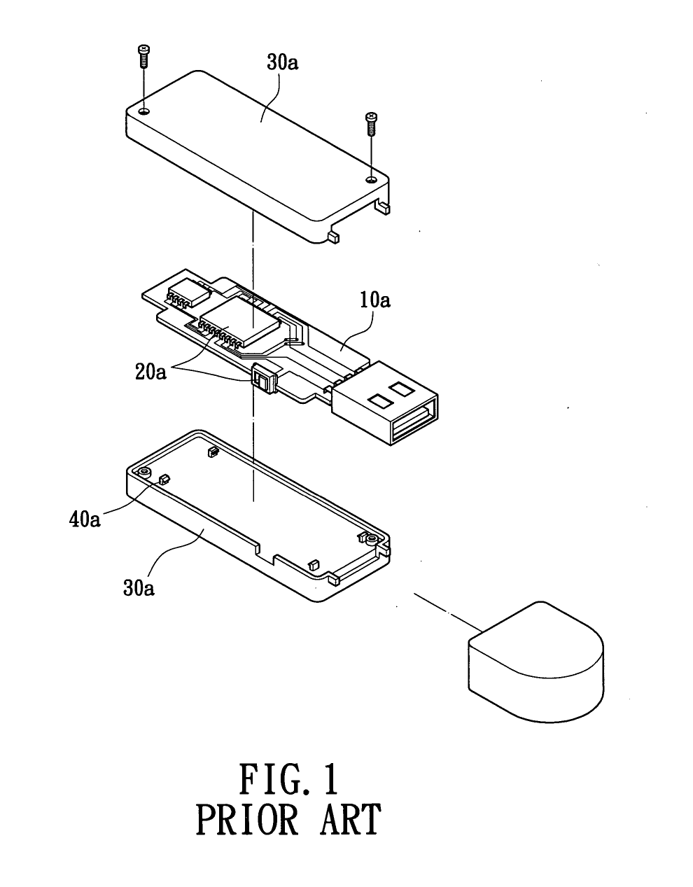

FIG. 2 is an exploded perspective view of a flash drive of the present invention;

FIG. 3 is an exploded partial view of a flash drive of the present invention;

FIG. 4 is a cross-sectional view of a flash drive of the present invention;

FIG. 5 is a exploded partial view of a mouse of the present invention; and

FIG. 6 is a schematic illustration of a circuit unit of the present invention.

### DETAILED DESCRIPTION OF THE PREFERRED EMBODIMENTS

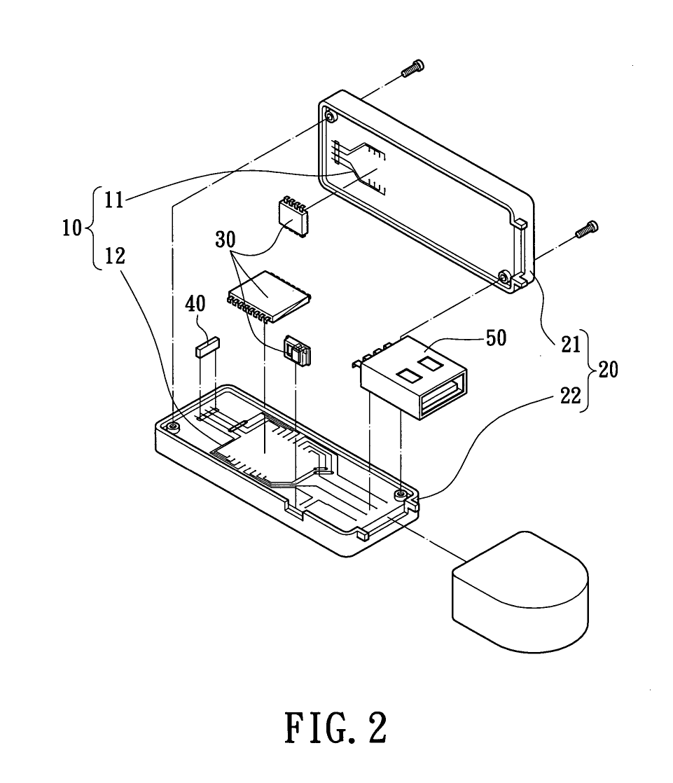

As shown in FIG. 2, the present invention provides a shell device with a circuit unit, wherein a circuit unit 10 is arranged on the inner surface of a shell 20 to reduce the assembly time of electronic components and save the cost thereof.

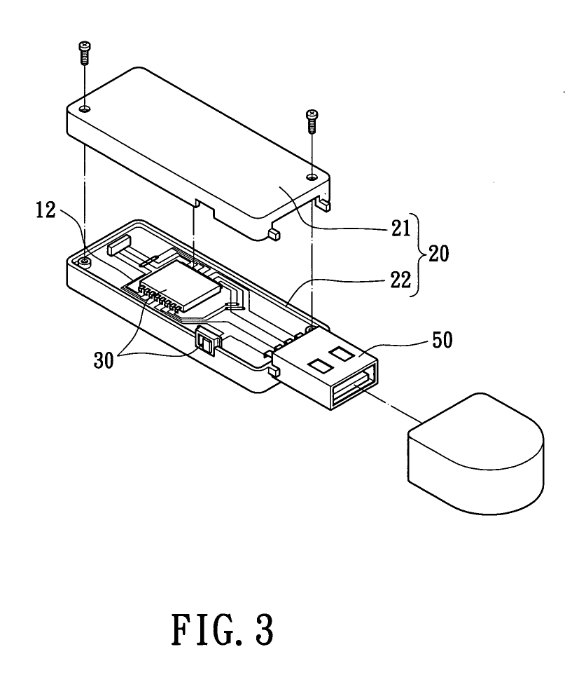

The shell device can apply to electronic products of simple circuit such as flash drives, business card scanners, mice, common scanners and so on. FIGS. 2 to 4 show a flash drive having a shell device with a circuit unit. The device comprises a shell 20 and a circuit unit 10. The shell 20 includes an upper shell 21 and a lower shell 22, each having an inner surface and an outer surface. The circuit unit 10 has an upper circuit unit 11 and a lower circuit unit 12, which are arranged on the inner surfaces of the upper shell 21 and the lower shell 22, respectively. Electronic components 30 such as IC components, LEDs, resistors and so on can be electrically connected onto the upper circuit unit 11 or the lower circuit unit 12 by means of surface-mount device (SMD) or wire bonding. The upper circuit unit 11 and the lower circuit unit 12 can be electrically connected together through an electric connection component 40, such as, for example, a conductive foam adhered thereon. An electronic connector 50 is also electrically connected to the circuit unit 10. It is only necessary to lock the upper shell 21 and the lower shell 22 to complete the electronic product.

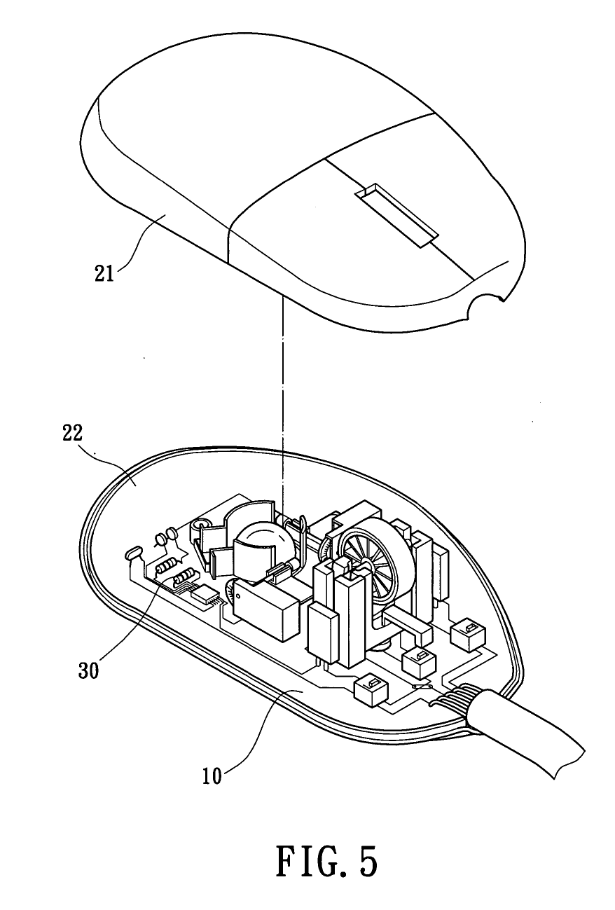

As shown in FIG. 5, the electronic product can be a mouse having the upper shell 21 and the lower shell 22. The circuit unit 10 can be arranged on the upper surface of the lower shell 22. Other electronic components 30 are electrically connected onto the circuit unit 10. It is only necessary to assemble other mechanisms and components like a roller on the upper surface of the lower shell 22 and then securely fasten the upper shell 21 to the lower shell 22 to complete the assembly of the mouse.

Therefore, the shell device with a circuit unit can reduce installation of printed circuit board and fastening components or locking components of a shell to save the time of assembling the printed circuit board on the shell and the processing procedure. Moreover, the circuit unit is modular, and can be printed or adhered on the inner surface of the shell. The outer shape of the shell of the electronic product can be arbitrarily changed, and it is not necessary to design extra circuit units. The design of fastening components or locking components of the shell can also be saved. Therefore, the processing cost of mold can be lowered to enhance the competitive capability of the electronic product.

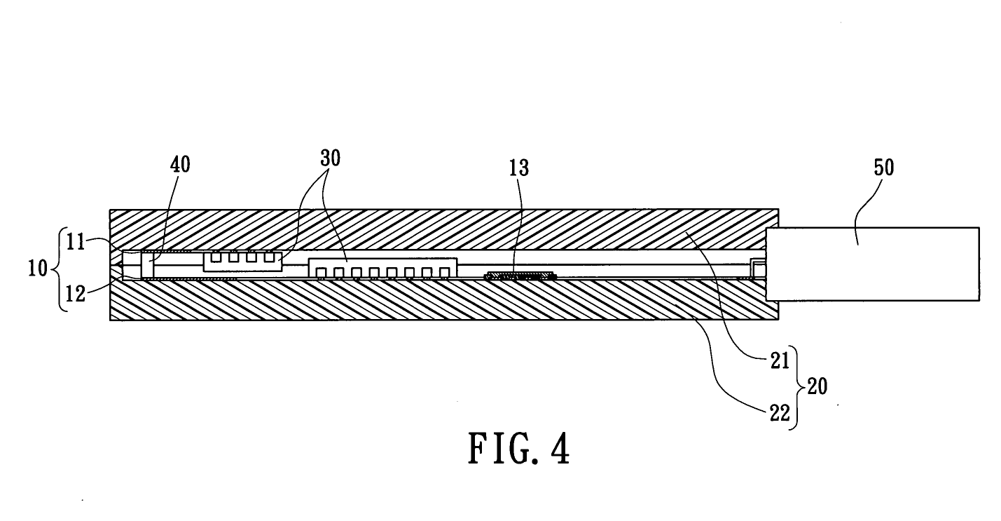

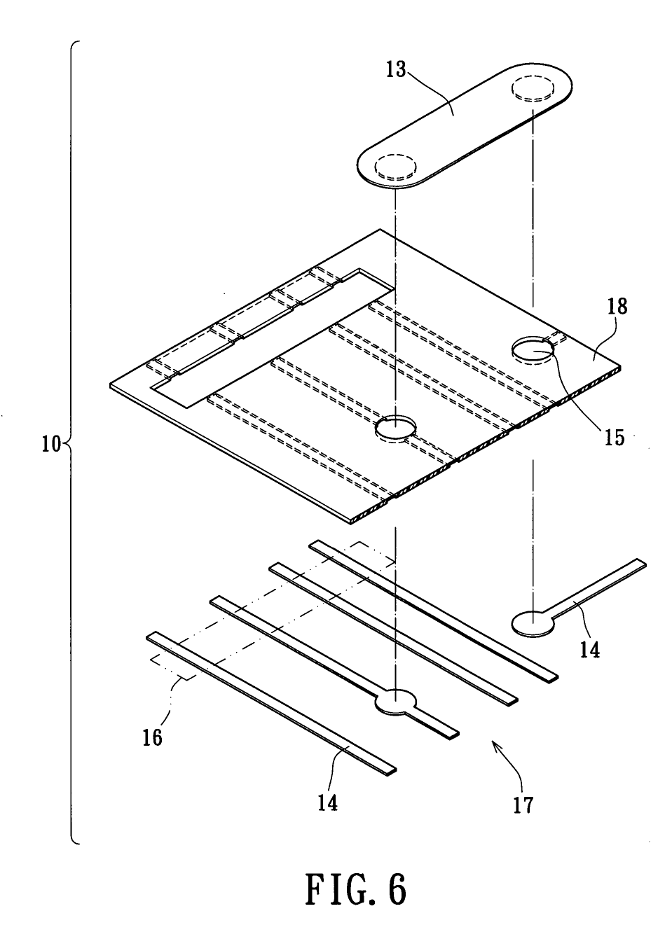

As shown in FIG. 6, the circuit unit 10 can be adhered or printed on the inner surface of the shell 20. When the circuit unit 10 is printed on the inner surface of the shell 20, the inner surface of the shell 20 needs to be planar to facilitate printing on the inner surface of the shell 20. The circuit unit 10 has a conducting layer 17, an insulating layer 18 and an electrical connection layer 13. The insulating layer 18 covers the conducting layer 17. The conducting layer 17 forms a plurality of wires, and the insulating layer 18 forms a plurality of through holes 16. Part of the wires are exposed by the through hole 15. The electric connection layer 13 is arranged between the wires 14 to be electrically connected together and is extended into the through holes 15 to electrically connect the wires 14 of the conducting layer 17, thereby forming the circuit unit 10. A plurality of layers can thus be formed. The conducting layer 17 has an exposed portion 16 not covered by the insulating layer 18 and the electric connection layer 13 so that the electronic components 15 (as shown in FIGS. 2 and 5) can be electrically connected thereonto. The exposed portion 16 can also be used as an electric connection portion of the electric connection component 40 to achieve electric connection between the upper circuit unit 11 and the lower circuit unit 12 (as shown in FIG. 4). Therefore, the circuit unit 10 can be arranged on the inner surface of the shell 20 of any shape in a modular way.

To sum up, the shell device with a circuit unit of the present invention can reduce installation of printed circuit board to reduce the processing procedure and time and also reduce the design cost of shell and the mold cost. Moreover, the circuit unit is modular, and can be arranged on the inner surface of a shell of any shape.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A shell device with a circuit unit comprising:
a shell having an inner surface; and
a circuit unit arranged on said inner surface of said shell.

2. The shell device with a circuit unit as claimed in claim 1, wherein said shell has an upper shell and a lower shell each having an inner surface, and said circuit unit has an upper circuit unit and a lower circuit unit are arranged on said inner surfaces of said upper shell and said lower shell, respectively.

3. The shell device with a circuit unit as claimed in claim 2, further comprising an electric connection component, which is electrically connected said upper circuit unit and said lower circuit unit.

4. The shell device with a circuit unit as claimed in claim 3, wherein said electric connection component is a conductive foam.

5. The shell device with a circuit unit as claimed in claim 1, wherein said circuit unit has a conducting layer, an insulating layer and an electrical connection layer, said conducting layer forms a plurality of wires, said insulating layer covers said wires, said insulating layer has a plurality of through holes, part of said wires are exposed by said through hole, and said electric connection layer is arranged between said wires on said insulating layer and is extended into said through holes to connect electrically said wires.

6. The shell device with a circuit unit as claimed in claim 5, wherein said conducting layer has an exposed portion not covered by said insulating layer and said electric connection layer.

7. The shell device with a circuit unit as claimed in claim 6, further comprising an electric connection component electrically connected to said exposed portion of said conducting layer.

8. The shell device with a circuit unit as claimed in claim 6, further comprising electronic components electrically connected to said exposed portion of said conducting layer.

9. The shell device with a circuit unit as claimed in claim 1, wherein said circuit unit is adhered on said inner surface of said shell.

10. The shell device with a circuit unit as claimed in claim 1, wherein said circuit unit is printed on said inner surface of said shell.

11. A shell device with a circuit unit comprising:
a shell including an upper shell and a lower shell, each having an inner surface;
a circuit unit including an upper circuit unit and a lower circuit unit, said upper circuit unit and said lower circuit unit being arranged on said inner surfaces of said upper shell and said lower shell, respectively; and
an electric connection component electrically connected between said upper circuit unit and said lower circuit unit.

12. The shell device with a circuit unit as claimed in claim 11, wherein said electric connection component is a conductive foam.

13. The shell device with a circuit unit as claimed in claim 11, wherein said circuit units have a conducting layer, an insulating layer and an electrical connection layer, said conducting layer forms a plurality of wires, said insulating layer covers said wires, said insulating layer has a plurality of through holes, part of said wires are exposed by said through hole, and said electric connection layer is arranged between said wires on said insulating layer and is extended into said through holes to connect electrically said wires.

14. The shell device with a circuit unit as claimed in claim 13, wherein said conducting layer has an exposed portion not covered by said insulating layer and said electric connection layer.

15. The shell device with a circuit unit as claimed in claim 14, further comprising an electric connection component electrically connected to said exposed portion of said conducting layer.

16. The shell device with a circuit unit as claimed in claim, 14 further comprising electronic components electrically connected to said exposed portion of said conducting layer.

17. The shell device with a circuit unit as claimed in claim 11, wherein said upper circuit unit and said lower circuit unit are adhered on said inner surfaces of said upper shell and said lower shell, respectively.

18. The shell device with a circuit unit as claimed in claim 11, wherein said upper circuit unit and said lower circuit unit are printed on said inner surfaces of said upper shell and said lower shell, respectively.
